(19) United States
(12) Patent Application Publication
(10) Pub. No.: US 2014/0218046 A1
(43) Pub. Date: Aug. 7, 2014

(54) WIRING CONNECTION CHECK METHOD AND CONNECTION CHECK SYSTEM

(71) Applicant: MITSUBISHI AIRCRAFT CORPORATION, Aichi (JP)

(72) Inventors: Yoshihiro Nakayama, Tokyo (JP); Koji Toyama, Tokyo (JP); Satoshi Suehiro, Tokyo (JP)

(21) Appl. No.: 14/240,962

(22) PCT Filed: Oct. 2, 2012
(86) PCT No.: PCT/JP2012/006305

§ 371 Date: Feb. 25, 2014

(30) Foreign Application Priority Data
Oct. 19, 2011 (JP) 2011-229312

(51) Int. Cl. G01R 31/04

(52) U.S. Cl. CPC G01R 31/041
USPC 324/538

(57) ABSTRACT

The present invention relates to a wiring connection check method in a wiring structure in which terminal devices are connected with a cable via relay devices and the cable is connected to the terminal devices and the relay devices via connectors. Connection information indicating a connecting relation between the connectors and the cable and a connecting relation between the connectors and any of the terminal devices and the relay devices is stored in a connection table database. In the connection check method of the present invention, a target connector to be checked is designated from among the connectors, and a connection route from the target connector to a connection end thereof is identified by sequentially tracing the connection information.

### TECHNICAL FIELD

The present invention relates to a method and system of checking a connection route in a wiring structure in which a plurality of electronic devices are connected to each other with electric wires (hereinafter also referred to as cables) via connectors.

### BACKGROUND ART

For example, in a system configured by connecting an input device, a control device, and an output device together with wire harnesses (hereinafter simply referred to as harnesses), it is required, after the system is assembled, to check whether electric wires forming the harnesses are connected through an appropriate route. However, if the system has many harnesses and many terminal devices such as input devices or many relay devices, it is not easy for a person other than a system designer to check the validity of the connection route from a plurality of wiring diagrams across which the connection route goes.

Various methods for supporting harness design have been proposed so far, such as the one disclosed in Patent Literature 1. For example, the invention disclosed in Patent Literature 1 presumes a system in which a three-dimensional model designed with a three-dimensional Computer Aided Design (CAD) is used to route and design harnesses on this three-dimensional model so that a problem in the harnesses can be found in this design process as much as possible. Most of all, the invention disclosed in Patent Literature 1 provides a harness design support system in consideration of physical properties of the harnesses such as stiffness and minimum radius of curvature.

### CITATION LIST

### Patent Literature

### Patent Literature 1: Japanese Patent No. 4235180

### SUMMARY OF THE INVENTION

### Technical Problems to be Solved by the Invention

However, while prior arts including the one disclosed in Patent Literature 1 can support harness design, the prior arts do not disclose an effective proposal regarding a validity check of a connection route. Moreover, when a new design support system is introduced, an enormous database library including information about wiring components and cables has to be reconstructed. Furthermore, a drawing database previously created in a wiring drawing system cannot be utilized, and thus, to make a partial improvement, wirings have to be redesigned from scratch.

The present invention was made based on the problems as described above, and has an object of providing a wiring connection check method and connection check system allowing a person other than a system designer to easily check a connection route for each single line even in a large system.

### Solution to the Problems

In any complex wiring, information indicating connections can be summarized as the following (a) and (b):

(a) information about a connection between a connector(s) and a cable(s), and

(b) information about a connection between a connector(s) and a terminal device(s) or a relay device(s).

Therefore, by storing relations of cables connected to connectors into a database and tracing a connection route, connection information can be grasped. Thus, the present invention disclosed herein relates to a wiring connection check method in a wiring structure in which one or a plurality of first terminal devices and one or a plurality of second terminal devices are connected with a cable via one or a plurality of relay devices and the cable is connected to the first terminal devices, the second terminal devices, and the relay devices via connectors.

The connection check method of the present invention includes connection information that indicates a connecting relation between the connectors and the cable and a connecting relation between the connectors and any of the first terminal devices, the second terminal devices, and the relay devices.

In the connection check method of the present invention, a target connector to be checked is designated from among the connectors and a connection route from the target connector to a connection end thereof is identified by sequentially tracing the connection information.

Note that, in the case (a) described above, the connectors and the cables have a one-to-one correspondence when a branching from a connector is not allowed and the connectors and the cables have a one-to-plural correspondence when a branching from a connector is allowed. Also, in the case (b) described above, the connectors and the terminal devices (or the relay devices) normally have a one-to-plural correspondence. Here, in a relay connector formed with a combination of a male connector and a female connector, it can be assumed that the male connector and a virtual relay device have a one-to-one connection and the female connector and a virtual relay device have a one-to-one connection.

In the wiring connection check method of the present invention, when a plurality of the connection routes from the target connector to the connection end are present, it is preferable that a plurality of the connection routes be identified and the plurality of identified routes be matched against each other.

By matching the plurality of identified connection routes against each other, it can be checked whether consistency in the plurality of identified connection routes is ensured.

In the wiring connection check method of the present invention, the connection information preferably includes cable information including a type, thickness, and number of cables at an arbitrary point, and the cable information is preferably identified when the connection route is identified. This is preferable because the cable information can also be obtained.

In the wiring connection check method of the present invention, by using the connection information, any one component among the cables, the first terminal devices, the second terminal devices, and the relay devices can be designated as a target component in place of the target connector, and the connection route from the target component to the connection end thereof can be identified by sequentially tracing the connection information.

The present invention can also be viewed as a wiring connection check system. That is, a wiring connection check system in a wiring structure of the present invention in which one or a plurality of first terminal devices and one or a plurality of second terminal devices are connected with a cable via one or a plurality of relay devices and the cable is connected to the first terminal devices, the second terminal devices, and the relay devices via connectors, the system comprising: a database having stored therein connection information indicating a connecting relation between the connectors and the cable and a connecting relation between the connectors and any of the first terminal devices, the second terminal devices, and the relay devices; and a processing unit configured to, when a target connector to be checked is designated from among the connectors, identify a connection route from the target connector to a connection end thereof by sequentially tracing the connection information.

In this wiring connection check system, when a plurality of the connection routes from the target connector to the connection end are present, the processing unit preferably identifies the plurality of the connection routes and matches the plurality of routes against each other.

Furthermore, in the database of the wiring connection check system, either one or both of the connection information about the connectors and the cable and the connection information about the connectors and any of the devices preferably include cable information including a type, thickness, and number of cables at an arbitrary point, and the processing unit preferably identifies the cable information when the connection route is identified.

Still further, when any one component of the cables, the first terminal devices, the second terminal devices and the relay devices is designated as a target component in place of the target connector, the processing unit can identify a connection route from the target component to a connection end thereof by sequentially tracing the connection information.

### Advantageous Effect of the Invention

According to the present invention, a person other than the system designer can easily identify a connection route for each single electric wire.

### BRIEF DESCRIPTION OF THE DRAWINGS

FIG. 1 is a diagram of the structure of a wiring connection check system in an embodiment;

FIG. 2 is a flowchart of a wiring connection check procedure;

FIG. 3 is a diagram of a wiring example in which cables, connectors, terminal devices, and relay devices are connected;

FIG. 4 is a diagram of a wiring example in which cables, connectors, terminal devices, and relay devices are connected;

FIG. 5 is a diagram of connection information in which the connectors used in the wiring example shown in FIG. 3 and FIG. 4 and their connecting destinations (connectors or devices) are stored as being associated with each other;

FIG. 6 is a diagram of the connection information shown in FIG. 5 in which the connectors are sorted in ascending order and duplicated information is further deleted;

FIG. 7 is a diagram showing the connection information of FIG. 6 (connection information A) and also connection information (connection information B) in which the connectors and connecting destinations in the connection information of FIG. 6 are horizontally switched;

FIG. 8 is a diagram of connection table data obtained by sorting the connectors in the connection information of FIG. 7 (the connection information A and B) in ascending order; and

FIG. 9 is a diagram of a searching procedure for identifying a connecting destination of a pin (pin No. 31) of a connector (P91405) in the connection table data of FIG. 8.

### DESCRIPTION OF EMBODIMENT

The present invention is described in detail below based on an embodiment shown in the attached drawings.

In a connection check system 10 for a wire harness according to the present embodiment, by designating a target connector to be checked, a connection route from the target connector to a connection end of the target connector can be identified.

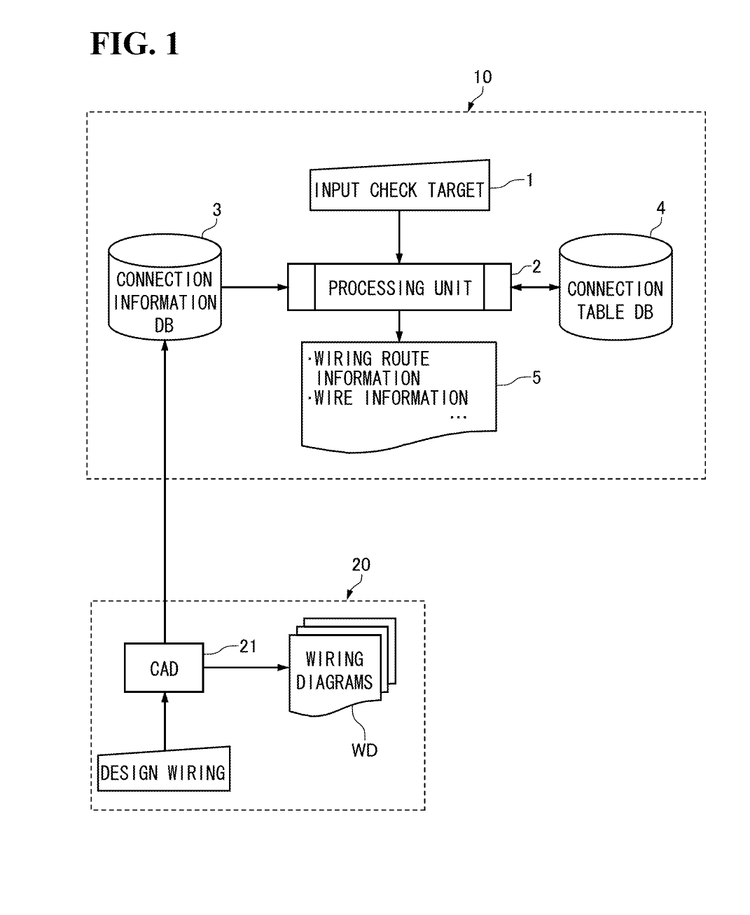

As shown in FIG. 1, the connection check system 10 includes an input unit 1, a processing unit 2, a connection information database 3, a connection table database 4, and a display unit 5. The connection check system 10 can be configured with a personal computer or another computer device.

The connection check system 10 is connected to a wiring drawing system 20. The wiring drawing system 20 is also configured with a computer device.

### [Outline of Connection Check System 10]

The input unit 1 is a portion to which information about a connector (a target connector) whose connecting relation is desired to be identified by the connection check system 10 is inputted. The input unit 1 can be configured with a keyboard as a computer input device. Note that while an example is described below in which information about a connector is inputted to the input unit 1, any of a terminal device and a relay device, which will be described below, as well as a cable can be taken as a target (a target component) desired to be identified and a connection route among these target components can be identified.

The processing unit 2 reads connection information stored in the connection information database 3 to generate connection table data. The processing unit 2 also reads the connection table data stored in the connection table database 4 to perform a search for identifying a connection route from the target connector to its connection end. The connection information and the connection table will be described in detail further below.

The display unit 5 displays the results of processes performed by the processing unit 2. The display unit 5 can be configured with a display keyboard as a computer display device.

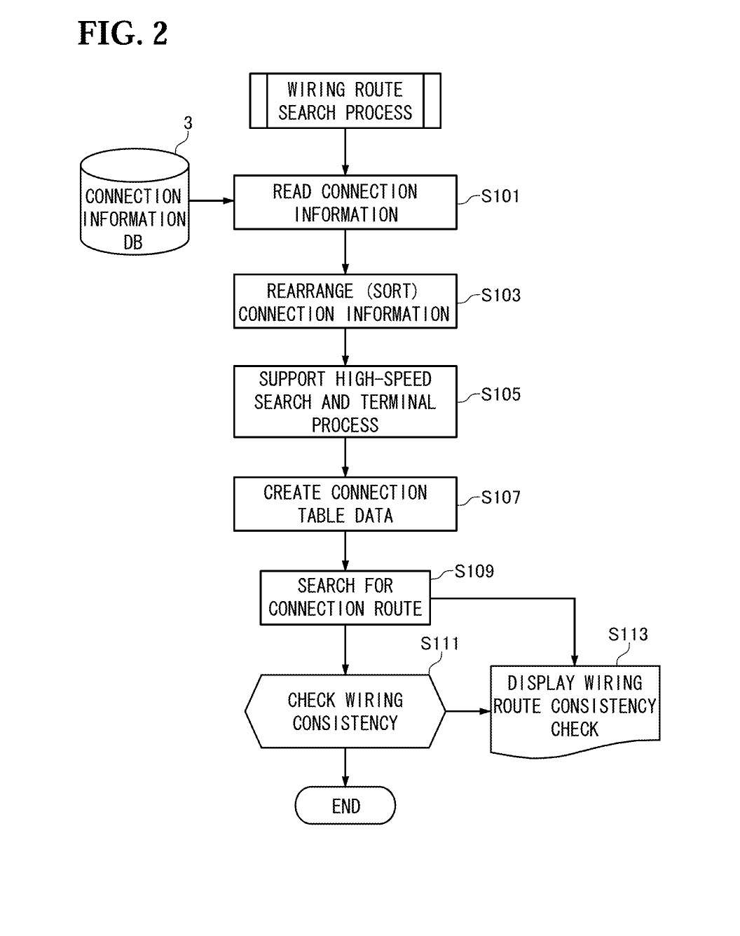

The above-structured connection check system 10 searches for a connection route by following a procedure shown in FIG. 2 and also checks consistency of the connection route, details of which will be described further below.

### [Outline of Wiring Drawing System 20]

The wiring drawing system 20 includes a CAD 21. The CAD 21 obtains connection information regarding connectors, cables, and devices in accordance with a wiring designing operation to create a wiring diagram. The CAD 21 provides the obtained connection information to the connection information database 3 in the connection check system 10.

### [Example of Wiring Diagram]

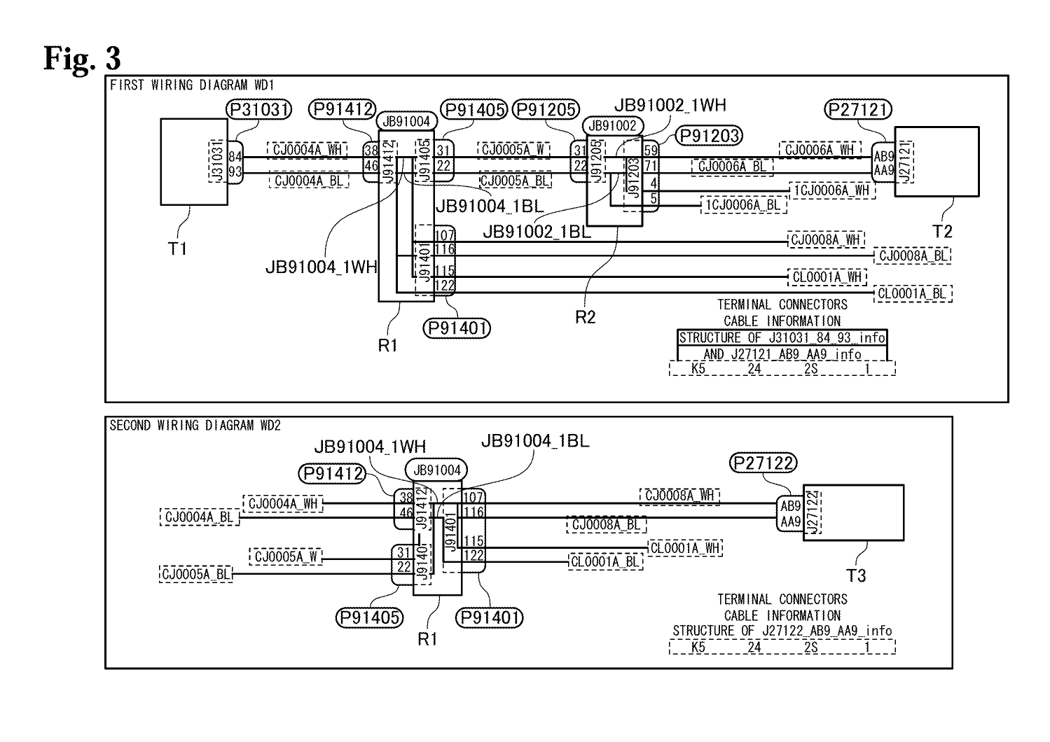

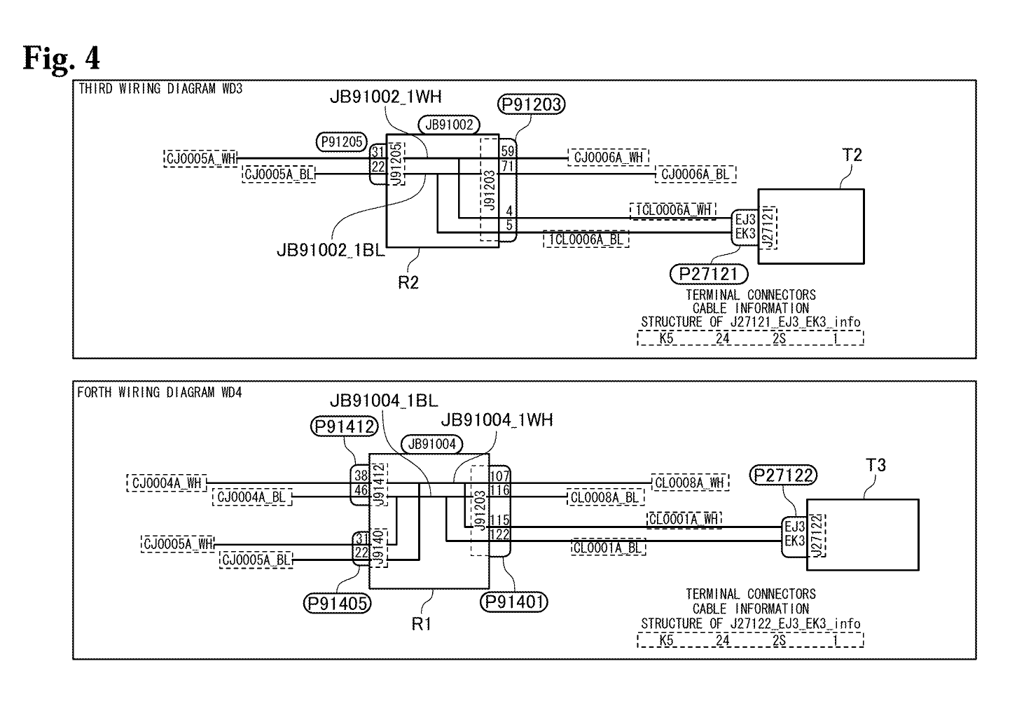

An example of a wiring diagram (hereinafter noted as a wiring diagram WD) created by the CAD 21 is shown in FIG. 3 and FIG. 4. An outline of the wiring diagram WD is described below.

The wiring diagram WD shows wirings among a terminal device T1 (a first terminal device), a terminal device T2 (a second terminal device), and a terminal device T3 (a third terminal device), and is divided into four, that is, a first wiring diagram WD1 (in an upper part of FIG. 3), a second wiring diagram WD2 (in a lower part of FIG. 3), a third wiring diagram WD3 (in an upper part of FIG. 4), and a fourth wiring diagram WD4 (in a lower part of FIG. 4).

As shown in the first wiring diagram WD1 (FIG. 3), a relay device R1 (JB91004) and a relay device R2 (JB91002) are interposed between the terminal device T1 and the terminal device T2. That is, the first wiring diagram WD1 shows that the terminal device T1 and the relay device R1 are connected to each other, the relay device R1 and the relay device R2 are connected to each other, and further the relay device R2 and the terminal device T2 are connected to each other.

Also, as shown in the first wiring diagram WD1 (FIG. 3) and the second wiring diagram WD2 (FIG. 3), the terminal device T3 is connected to the terminal device T1 via the relay device R1 (JB91004). Note that while the second wiring diagram WD2 mainly shows the terminal device T3, the second wiring diagram WD2 also redundantly shows the relay device R1 and other necessary cables and connectors as overlapping the first wiring diagram WD1 so as to clarify a connecting relation with the surroundings. The same applies to the third wiring diagram WD3 and the fourth wiring diagram WD4.

Furthermore, the third wiring diagram WD3 (FIG. 4) shows that the terminal device T2 and the relay device R2 are connected to each other. While the fact that the terminal device T2 and the relay device R2 are connected to each other is also shown in the first wiring diagram WD1, the third wiring diagram WD3 shows that the terminal device T2 and the relay device R2 are connected to each other via a pin of a connector different from that in the first wiring diagram WD1. This will be described further below.

Still further, the fourth wiring diagram WD4 (FIG. 4) shows that the terminal device T3 and the relay device R1 are connected to each other. While the fact that the terminal device T3 and the relay device R1 are connected to each other is also shown in the second wiring diagram WD2, the fourth wiring diagram WD4 shows that the terminal device T3 and the relay device R1 are connected to each other via a pin of a connector different from that in the second wiring diagram WD2. This will be described further below.

Here, signs shown in the wiring diagrams WD are defined as follows. Note that a terminal connector refers to a connector provided to any of the terminal devices T1 to T3.

Pxxxxx: male connector number
Jxxxx: female connector number
JBxxxxx: relay device number
xCxxxxxx: cable number
xxxxx_yy: yy is a pin number of a connector or a single line identification number and xxxxx is a connector number
Jxxxxx_yy_yy_info: cable information of a terminal connector
(the above represents an example of cable attribute information.)
Kx x xS x: also representing an example of cable attribute information indicating, from left, a group name of a wire harness, a line diameter of the cable, information about a shield provided to the cable, and the number of cables.

Several examples of the signs defined as described above are described with reference to the wiring diagrams WD.

In the first wiring diagram WD1, the terminal device T1 is provided with a female connector J31031, and to this female connector J31031, a male connector P31031 is connected.

Via the female connector J31031 and the male connector P31031, a pair of cables CJ0004A_WH and CJ0004A_BL have their one ends connected to the terminal device T1. The cables CJ0004A_WH and CJ0004A_BL are connected to pins (or terminals) identified as pin numbers 84 and 93, respectively, in the female connector J31031 and the male connector P31031. In the present embodiment, these two cables CJ0004A_WH and CJ0004A_BL are made into one bundle (a line bundle) as a harness. While paired cables described below are also made into one bundle in the same manner, in general the number of cables as a bundle is arbitrarily defined as one or more, and is not restricted to two.

The cables CJ0004A_WH and CJ0004A_BL have their other ends connected to the relay device R1 (JB91004) via a male connector P91412 and a female connector J91412. The cables CJ0004A_WH and CJ0004A_BL are connected to pins identified as pin numbers 38 and 46, respectively, in the male connector P91412 and the female connector J91412.

Next, with reference to the first wiring diagram WD1 and the second wiring diagram WD2, a cable CJ0008A_WH in the first wiring diagram WD1 and a cable CJ0008A_WH in the second wiring diagram WD2 are identical to each other, and a cable CJ0008A_BL in the first wiring diagram WD1 and a cable CJ0008A_BL in the second wiring diagram WD2 are identical to each other. That is, the first wiring diagram WD1 and the second wiring diagram WD2 show that the cables CJ0008A_BL and CJ0008A_BL are connected to the terminal device T3.

In the first wiring diagram WD1 and the second wiring diagram WD2, a cable CL0001A_WH and a cable CL0001A_BL are identical to each other. Furthermore, with reference also to the fourth wiring diagram WD4, the relay device R1 and the terminal device T3 are connected with the cables CL0001A_WH and CL0001A_BL. When a connecting portion on a terminal device T3 side is viewed, the cables CL0001A_WH and CL0001A_BL are connected to the terminal device T3 via a male connector P27122 and a female connector J27122. As shown in the second wiring diagram WD2, via the male connector P27122 and the female connector J27122, the cables CJ0008A_BL and CJ0008A_WH are connected to the terminal device T3. However, the cables CL0001A_WH and CL0001A_BL are connected to pins identified as pin numbers EJ3 and EK3, respectively (the fourth wiring diagram WD4), and the cables CJ0008A_BL and CJ0008A_WH are connected to pins identified as pin numbers AB9 and AA9, respectively (the second wiring diagram WD2). That is, the second wiring diagram WD2 and the fourth wiring diagram WD4 show that the relay device R1 and the terminal device T3 are connected with bundles of two systems.

Next, with reference to the first wiring diagram WD1 and the third wiring diagram WD3, the relay device R2 and the terminal device T2 are connected with cables 1CL0006A_WH and 1CL0006A_BL. As shown in the third wiring diagram WD3, the cables 1CL0006A_WH and 1CL0006A_BL are connected to the terminal device T2 via a male connector P27121 and a female connector J27121, respectively. As shown in the first wiring diagram WD1, via the male connector P27121 and the female connector J27121, cables CJ0006A_WH and CJ0006A_BL are connected to the terminal device T2. However, the cables 1CL0006A_WH and 1CL0006A_BL are connected to pins identified as pin numbers EJ3 and EK3, respectively (the third wiring diagram WD3), and the cables CJ0006A_WH and CJ0006A_BL are connected to pins identified as pin numbers AB9 and AA9, respectively (the first wiring diagram WD1). That is, the first wiring diagram WD1 and the third wiring diagram WD3 show that the relay device R2 and the terminal device T2 are connected with bundles of two systems.

### [Example of Connection Information]

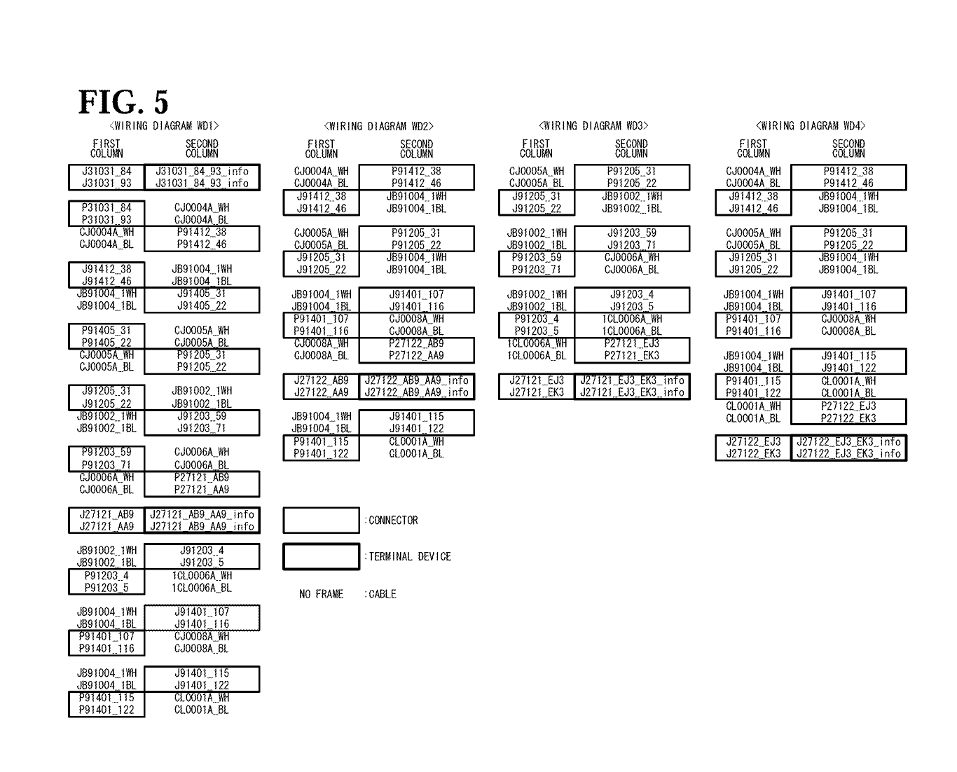

Meanwhile, FIG. 5 shows information indicating a connecting relation among the components (the terminal devices, the relay devices, the cables, and the connectors) in the wiring diagrams WD described above (hereinafter referred to as connection information). This connection information is stored in the connection information database 3. The processing unit 2 reads the connection information from the connection information database 3 when performing a connection route search (S101 in FIG. 2).

The information indicating the connecting relation herein refers to information indicating components directly connected to each other as being associated with each other. For example, “J31031_84 J31031_84_93_info” and “J31031_93 J31031_84_93_info” at the uppermost stage in <Wiring Diagram WD1> in FIG. 5 indicate that the terminal device T1 is connected to the pins identified as the pin numbers 84 and 93 of the female connector J31031. Note that since only one single line (cable) can be connected to a pin of a connector, the pin of the connector and the cable (single line) have a one-to-one correspondence.

Also, at the next stage in <Wiring Diagram WD1> in FIG. 5, “P31031_84_CJ0004_WH” indicates that the cable CJ0004_WH is connected to the pin identified as the pin number 84 of the male connector P31031, and “P31031_93 CJ0004_BL” indicates that the cable CJ0004_BL is connected to the pin identified as the pin number 93 of the male connector P31031.

The same applies to the other connection information shown in FIG. 5.

### [Rearrangement of Connection Information]

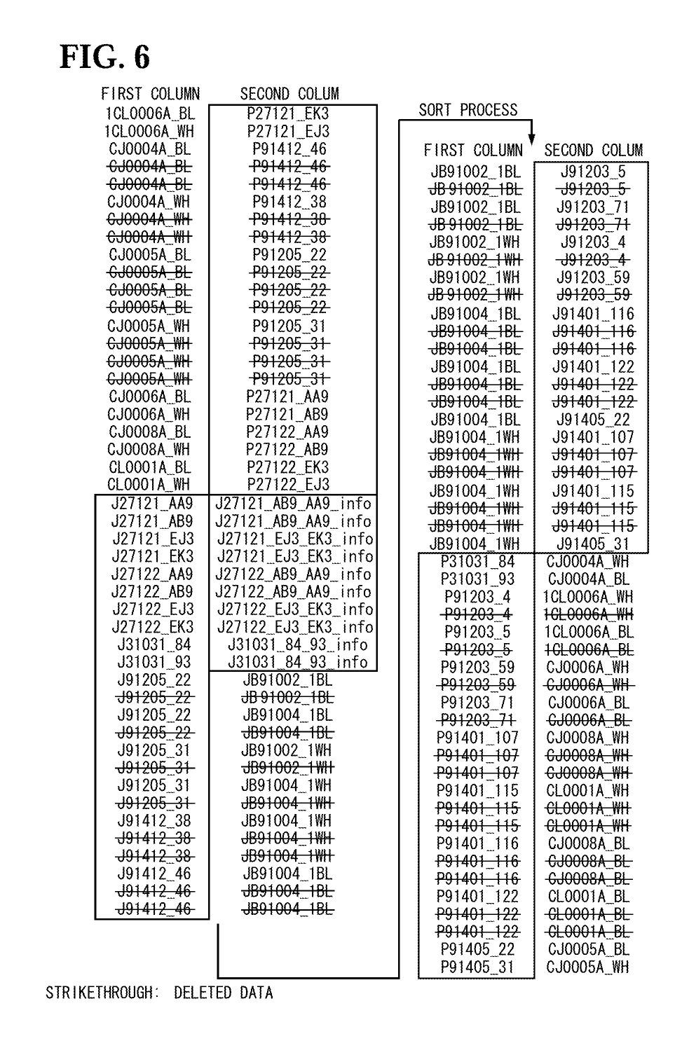

The connection information shown in FIG. 5 includes those redundantly described in the wiring diagrams WD. For example, the connecting relation between the cable CJ0004_WH and the male connector P91412 in the first wiring diagram WD1 is also shown in the second wiring diagram WD2 and the fourth wiring diagram WD4. As such, since the wiring diagrams WD include a one-to-plural connecting relation, such duplicated piece of connection information is deleted from the connection information shown in FIG. 5 in consideration of a later quick search. To this end, for example, the processing unit 2 deletes the duplicated piece of connection information after performing a sort process (rearrangement) with reference to the first column in FIG. 5 (S103 in FIG. 2). FIG. 6 shows the state after the sort process, and a strikethrough is attached onto a duplicated piece of connection information. In practice, each piece of connection information with a strikethrough is deleted from the connection information. Note that FIG. 6 covers all pieces of connection information shown in the first wiring diagram WD1 to the fourth wiring diagram WD4.

Next, the processing unit 2 also performs the following processes to ease the search (S105 and S107 in FIG. 2).

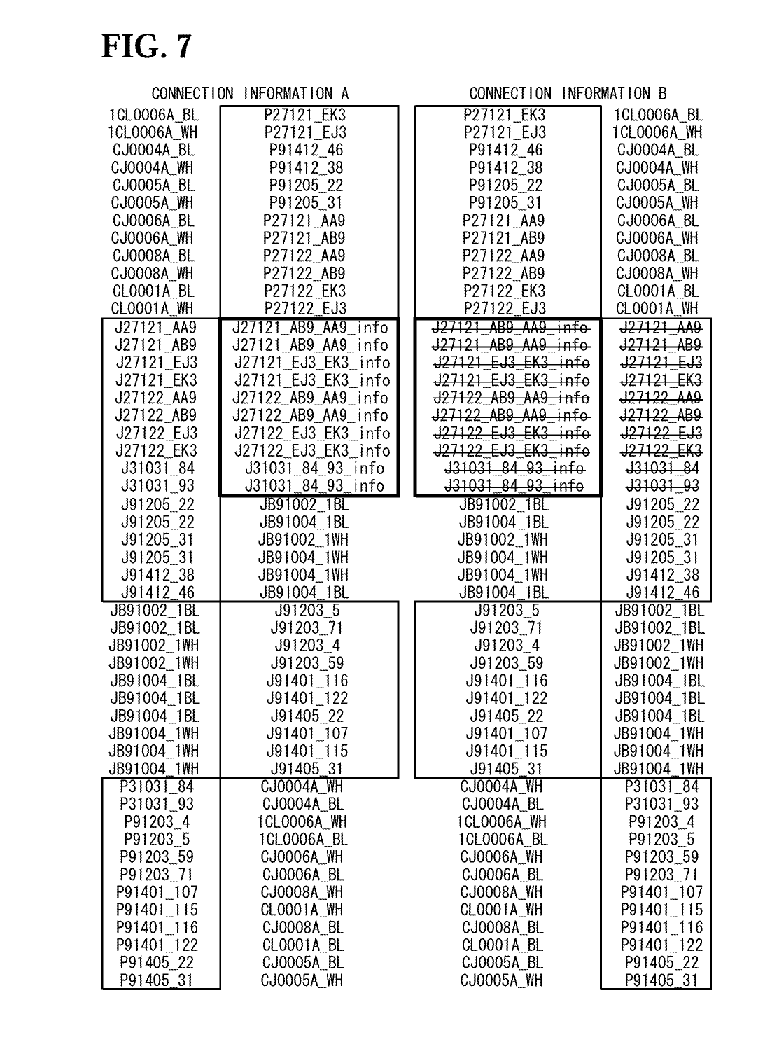

A connection information group B is generated with the first column and the second column being switched. Then, an originally existing connection information group A with the first column and the second column not being switched and the connection information group B are placed concurrently. The results are shown in FIG. 7. However, as for the connection information group B, pieces of information identifying the terminal devices T1 to T3 are deleted, as shown with strikethroughs (S105 in FIG. 2). In this manner, by eliminating the pieces of information corresponding to these terminal devices T1 to T3, a later search can end when reaching to any of the terminal devices T1 to T3, and also the cable information of the terminal connector can be grasped at that stage.

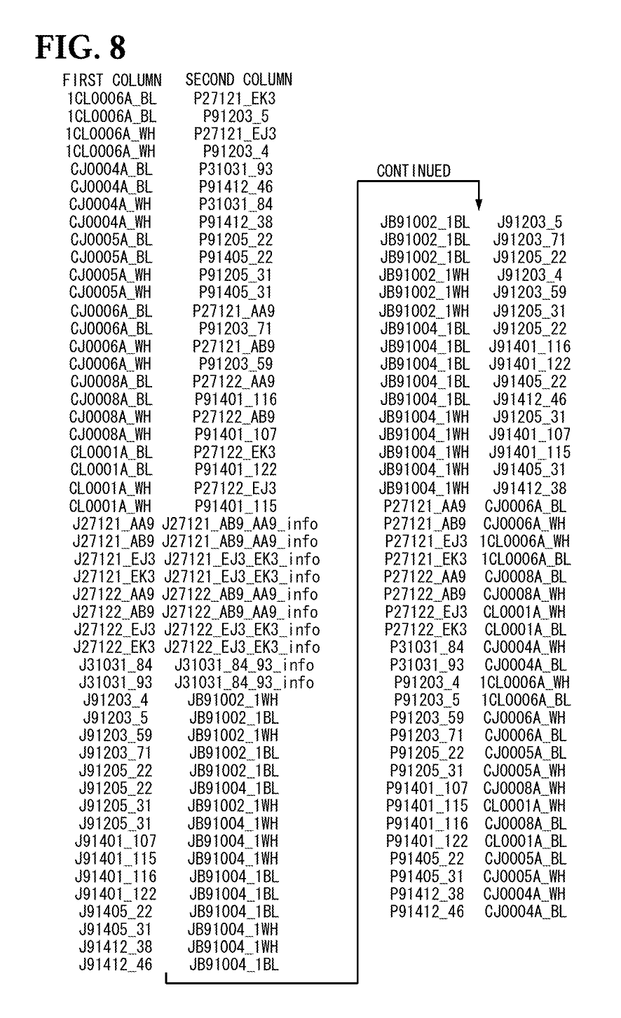

Furthermore, sorting is performed with reference to the first column to generate a connection table shown in FIG. 8 (S107 in FIG. 2).

### [Search Example]

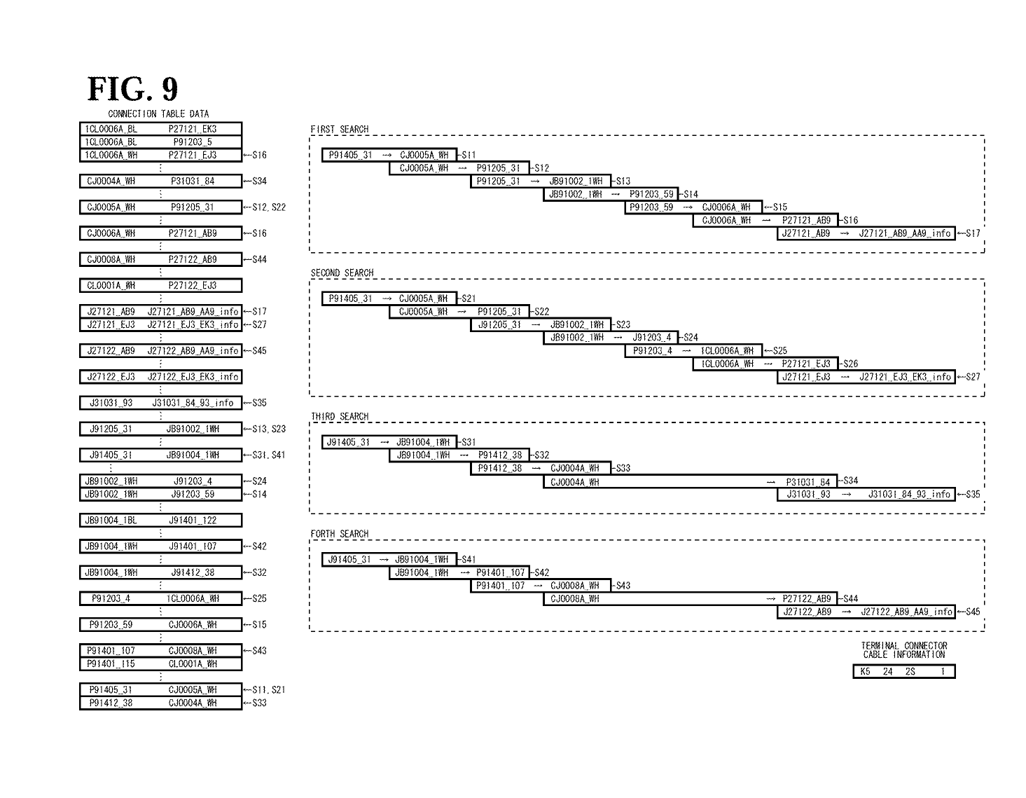

Next, the processing unit 1 performs a search for a connection route (S109 in FIG. 2). An example of a search for a connection end of a pin (a target connector) identified as a pin number 31 of the male connector P91405 (the relay device R1) is described with reference to FIG. 9. Note that while connection table data shown in FIG. 9 is identical to that of FIG. 8, portions unnecessary for the following description are omitted. Furthermore, the target connector is not meant to be restricted to the above, and any connector connected to any of the terminal devices T1 to T3 and the relay devices R1 and R2 can be taken as a target connector.

(a) First Search

From the connection table, a male connector “P91405_31” corresponds to a cable number “CJ0005A_WH” (step S11 of a first search in FIG. 9).

Next, from the connection table, the cable number “CJ0005A_WH” corresponds to a connector number “P91205_31” (step S12 of the first search in FIG. 9).

Next, from the connection table, a male connector “P91205_31” corresponds to a cable number “JB91002_1WH” (step S13 of the first search in FIG. 9).

Next, from the connection table, the cable number “JB91002_1WH” corresponds to a connector number “P91203_59 (step S14 of the first search in FIG. 9).

Thereafter, by tracing with a procedure similar to that at steps S15 to S17 (the first search in FIG. 9), the search reaches a terminal connector “J27121_AB9_AA9_info”. As such, a connection route from the male connector “P91405_31” to the female connector “J27121_AB9” is identified. Also, from the cable information of this terminal connector, the cable information of the search source “P91405_31” is revealed as follows.

The processing unit 2 can cause the connection route and the cable information to be displayed on the display unit 5 (S113 in FIG. 2). For example, by indicating the procedure of the first search shown in FIG. 9, the connection route can be displayed on the display unit 5. Note that the cable information described below represents a group name of the wire harness as K5, the line diameter of the cable, information about a shield provided to the cable, and the number of cables:

Cable Information “K5 24 2S 1”.

(b) Second Search

When a search is performed for a connection end (connection route) of the pin identified as the pin number 31 of the male connector “P91405” (the relay device R1) described above and cable information, the cable number “JB91002_1WH” also corresponds to a connector number “J91203_4” in addition to the connection number found at step S14 of the first search. Therefore, from here, by tracing a connection route different from that of the first search with a procedure indicated as a second search (S24 to S27) in FIG. 9, the search reaches a terminal connector “J27121_EJ3_EK3_info”. As such, a connection route from the male connector “P91405_31” to the female connector “J27121_EJ3” is identified. Furthermore, from the cable information of this terminal connector, the cable information of the search source “P91405_31” is revealed as follows:

Cable information “K5 24 2S 1”.

Note that steps S21 to S23 in the second search are similar to steps S11 to S13 in the first search.

(c) Third Search to Fourth Search

While the first search and the second search have been performed for the male connector “P91405_31”, searches are similarly performed for a pin of a female connector identified as “J91405_31” fitting in the pin of the connector identified as “P91405_31”, thereby grasping all of a plurality of connection routes that are present. Such an example is shown in FIG. 9 as a third search and a fourth search. The search procedure of the third search and the fourth search is similar to that of the first search and the second search, and therefore details are omitted herein. The female connector “J91405_31” corresponds to a cable number “JB91004_1WH” (step S31 of the third search in FIG. 9). And, the cable number “JB91004_1WH” corresponds to two connector numbers “P91412_38” and “P91401_107”, and thus the third search and the fourth search are performed by the processing unit 2.

Terminal connectors obtained from the third search and the fourth search are “J31031_84_93_info” and “J27122_AB9_AA9_info”, respectively, and their cable information are as follows.

Third search (cable information): “K5 24 2S 1”

Fourth search (cable information): “K5 24 2S 1”

[Consistency Check]

When searches for all connection routes are completed in the manner as described above, the processing unit 2 matches the pieces of cable information obtained in the respective searches against each other (S111 in FIG. 2). In the example of the first search to the fourth search described above, all pieces of cable information coincide with each other as “K5 24 2S 1”, and it has been confirmed that consistency in the searches is ensured (Sill in FIG. 2). The processing unit 2 causes the display unit 5 to display whether consistency in all pieces of cable information is ensured (S113 in FIG. 2).

As has been described in the foregoing, according to the present embodiment, a connection route search is performed based on the connection information (the database) obtained from the wiring diagrams WD. As such, in the present embodiment, a connection route search is performed without using a wiring CAD, and cable information can also be obtained.

In the present embodiment, if information about a wiring length is provided correspondingly to each relay device number and each cable number, a cable length can be found by totalizing the wiring length values for each connection route.

Furthermore, if a bundle (line bundle) number is associated as a collection of a plurality of single lines, all pieces of cable information about the cables included in that bundle (line bundle) can be easily obtained.

Still further, since only the results of connection information are enough to be provided for most of designers who refer to the wiring diagrams, no CAD license is required for those designers.

Note that the wiring structure used for describing the above embodiment is merely an example and it goes without saying that the present invention can be applied to another wiring structure.

Also, devises and equipment to which the wiring structure is applied are not restricted, and the present invention can be applied to various devises and equipment in which a terminal device and a relay device are connected to each other with a cable.

In addition, any of the structures described in the above embodiment can be selected or omitted, or modified into another structure as appropriate as long as such selection, omission, or modification does not deviate from the gist of the present invention.

### REFERENCE SIGNS LIST

1 input unit
2 processing unit
3 information database
4 connection table database
5 display unit
10 connection check system
20 wiring drawing system
R1, R2 relay device
T1, T2, T3 terminal device

1. A wiring connection check method in a wiring structure in which one or a plurality of first terminal devices and one or a plurality of second terminal devices are connected with a cable via one or a plurality of relay devices and the cable is connected to the first terminal devices, the second terminal devices, and the relay devices via connectors, wherein:
connection information is provided, the connection information indicating a connecting relation between the connectors and the cable and a connecting relation between the connectors and any of the first terminal devices, the second terminal devices, and the relay devices; and
a target connector to be checked is designated from among the connectors and a connection route from the target connector to a connection end thereof is identified by sequentially tracing the connection information.

2. The wiring connection check method according to claim 1, wherein
when a plurality of the connection routes from the target connector to the connection end are present, a plurality of the connection routes are identified, and the plurality of identified routes are matched against each other.

3. The wiring connection check method according to claim 1, wherein
the connection information includes cable information including a type, thickness, and number of cables at an arbitrary point, and
the cable information is identified when the connection route is identified.

4. The wiring connection check method according to claim 1, wherein
any one component among the cables, the first terminal devices, the second terminal devices, and the relay devices is designated as a target component in place of the target connector, and the connection route from the target component to the connection end thereof is identified by sequentially tracing the connection information.

5. A wiring connection check system in a wiring structure in which one or a plurality of first terminal devices and one or a plurality of second terminal devices are connected with a cable via one or a plurality of relay devices and the cable is connected to the first terminal devices, the second terminal devices, and the relay devices via connectors, the system comprising:
a database having stored therein connection information indicating a connecting relation between the connectors and the cable and a connecting relation between the connectors and any of the first terminal devices, the second terminal devices, and the relay devices; and
a processing unit configured to, when a target connector to be checked is designated from among the connectors, identify a connection route from the target connector to a connection end thereof by sequentially tracing the connection information.

6. The wiring connection check system according to claim 5, wherein
when a plurality of the connection routes from the target connector to the connection end are present, the processing unit identifies the plurality of the connection routes and matches the plurality of routes against each other.

7. The wiring connection check system according to claim 5, wherein
in the database,
either one or both of the connection information indicating the connecting relation between the connectors and the cable and the connection information indicating the connecting relation between the connectors and any of the devices include(s) cable information including a type, thickness, and number of cables at an arbitrary point, and
the processing unit identifies the cable information when the connection route is identified.

8. The wiring connection check system according to claim 5, wherein
when any one component of the cables, the first terminal devices, the second terminal devices and the relay devices is designated as a target component in place of the target connector, the processing unit identifies a connection route from the target component to a connection end thereof by sequentially tracing the connection information.
